(19) United States
(12) Patent Application Publication
(10) Pub. No.: US 2018/0226366 A1
(43) Pub. Date: Aug. 9, 2018

(54) SEMICONDUCTOR PACKAGE AND MANUFACTURING METHOD THEREOF

(71) Applicant: SAMSUNG ELECTRO-MECHANICS CO., LTD., Suwon-si (KR)

(72) Inventors: Se Jong KIM, Suwon-si (KR); Dong Tack MOON, Suwon-si (KR); Won Gi KIM, Suwon-si (KR)

(73) Assignee: SAMSUNG ELECTRO-MECHANICS CO., LTD., Suwon-si (KR)

(21) Appl. No.: 15/715,237

(22) Filed: Sep. 26, 2017

(30) Foreign Application Priority Data
Feb. 3, 2017 (KR) 10-2017-0015488

(51) Int. Cl. H01L 23/66; H01L 23/538; H01L 25/10; H01L 23/31; H01L 25/18; H01L 23/367; H03H 7/38; H01L 25/00; H01L 21/56; H01L 21/48; H01L 23/13; H01L 25/065

(52) U.S. Cl. CPC H01L 23/66; H01L 24/08; H01L 25/105; H01L 23/3121; H01L 23/5384; H01L 25/18; H01L 23/367; H03H 7/38; H01L 25/50; H01L 21/56; H01L 21/4857; H01L 23/5386; H01L 23/5383; H01L 23/13; H01L 25/0655; H01L 2225/1094; H01L 2223/6616; H01L 2223/6677; H01L 2924/19105; H01L 2924/19041; H01L 2924/19042; H01L 2223/6655; H01L 21/486; H01L 23/5389

(57) ABSTRACT

A semiconductor package includes a device embedded portion including a first substrate having a first device embedded therein and a second substrate disposed on the first substrate, a device mounting portion comprising a second device disposed on the device embedded portion, and a sealing portion for sealing the second device, and a second module mounted on a surface of the device embedded portion that is opposite of a surface on which the device mounting portion is disposed.

### CROSS-REFERENCE TO RELATED APPLICATION(S)

This application claims the benefit under 35 USC § 119(a) of Korean Patent Application No. 10-2017-0015488 filed on Feb. 3, 2017, in the Korean Intellectual Property Office, the entire disclosure of which is incorporated herein by reference for all purposes.

### BACKGROUND

### 1. Field

The following description relates to a semiconductor package and a manufacturing method thereof.

### 2. Description of Related Art

In order to use high-quality, high-capacity data at a high speed, a frequency band of a semiconductor package is increased. For example, in the case of a semiconductor package for wireless communications, a technique using a millimeter wave band of 27 GHz or more may be used.

When using the millimeter wave band, a wavelength of a frequency is reduced to millimeter standard. Thus, when a conventional semiconductor package structure is used, deteriorations in performance may occur.

Accordingly, there is demand for a semiconductor package capable of efficiently operating in the above-described high frequency band.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor package includes a device embedded portion including a first substrate having a first device embedded therein and a second substrate disposed on the first substrate, a device mounting portion comprising a second device disposed on the device embedded portion, and a sealing portion for sealing the second device, and a second module mounted on a surface of the device embedded portion that is opposite of a surface on which the device mounting portion is disposed.

The first device and the second device may be arranged such that respective active surfaces face each other with the second substrate therebetween.

The first device and the second device may be electrically connected through the second substrate.

The first device may be a front end module (FEM) device for wireless communications and the second device is a signal processing device for wireless communications.

The semiconductor package may further include a heat dissipating member comprising a metal material disposed on an inactive surface of the second device, one surface of the heat dissipating member being exposed externally of the sealing portion.

The second module may include a dielectric substrate, a radiation part disposed on a first surface of the dielectric substrate, connection electrodes disposed in a second surface of the dielectric substrate opposite the first surface and bonded to the device embedded portion by a conductive bonding member, and an interlayer connection conductor disposed on the dielectric substrate and electrically connecting the radiation part and the connection electrodes.

The device mounting portion may be disposed in the sealing portion and may include connection conductors having one end electrically connected to the device embedded portion and the other end exposed externally of the sealing portion.

The second substrate may include a third device including alternately stacked one or more insulating layers and one or more wiring layers disposed on the first substrate.

The third device may be connected to a path electrically connecting the first device and the second device and may be used for impedance matching of the first device and the second device.

The third device may include an inductor or a capacitor.

In another general aspect, a method of manufacturing a semiconductor package includes forming a device embedded portion in which a first device is embedded in a substrate, mounting a second device on one a first of the device embedded portion, and mounting an antenna module on a second surface of the device embedded portion opposite the first surface.

The mounting of the second device may include mounting the second device such that an active surface of the first device and an active surface of the second device face each other.

The forming of the device embedded portion may include embedding the first device in a first substrate, and forming a second substrate on the first substrate by alternately stacking one or more insulating layers and one or more wiring layers.

The forming of the second substrate may further include forming a third device electrically connected to the wiring layer. The third device may be electrically connected to a path electrically connecting the first device and the second device.

The method may further include forming a sealing portion configured to seal the second device and forming connection conductors penetrating the sealing portion and comprising a first end electrically connected to the device embedded portion and a second end exposed externally of the sealing portion.

The forming of the sealing portion may include partially removing the sealing portion to partially expose the second device.

Other features and aspects will be apparent from the following detailed description, the drawings, and the claims.

### BRIEF DESCRIPTION OF THE DRAWINGS

FIG. 1 is a schematic cross-sectional view illustrating an example of a semiconductor package.

FIGS. 2, 3, 4, 5, 6, 7, 8, and 9 are diagrams illustrating examples of manufacturing the semiconductor package shown in FIG. 1.

FIG. 10 is an exploded perspective view of an enlarged portion of the semiconductor package shown in FIG. 1 illustrating an example in which a first device and a second device are connected.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Expressions such as “first conductivity type” and “second conductivity type” as used herein may refer to opposite conductivity types such as N and P conductivity types, and examples described herein using such expressions encompass complementary examples as well. For example, an example in which a first conductivity type is N and a second conductivity type is P encompasses an example in which the first conductivity type is P and the second conductivity type is N.

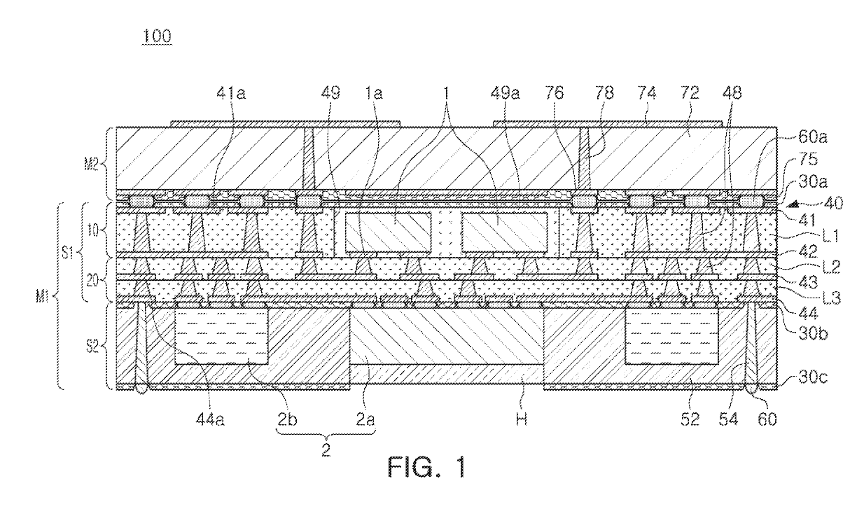

FIG. 1 is a schematic cross-sectional view illustrating an example of a semiconductor package.

Referring to FIG. 1, a semiconductor package 100 includes a first module M1 and a second module M2 stacked on the first module M1.

The first module M1 includes a device embedded portion S1 and a device mounting portion S2.

The device embedded portion S1 includes a substrate part 40 and at least one first device 1 embedded in a substrate part 40.

The substrate part 40 has insulating layers L1 to L3 and wiring layers 41 to 44 repeatedly stacked. The substrate part 40 also includes a device accommodating part 49 disposed therein.

The substrate part 40 includes a first substrate 10 constituting a core, a second substrate 20 stacked on the outside of the first substrate 10, and insulating protection layers 30a and 30b disposed on respective surfaces of the substrate part 40.

The first substrate 10 is configured as a double-sided substrate in which the wiring layers 41 and 42 are disposed on respective sides of the one insulating layer L1. However, the configuration of the present disclosure is not limited thereto. For example, the first substrate 10 may be configured as a multilayer substrate in which wiring layers and/or insulating layers are stacked in layers as necessary.

The second substrate 20 rewires a terminal 1a of the first device 1 and may be formed on the first substrate 10 through a build-up method. For example, the second substrate 20 may be formed by repeatedly stacking insulating layers L2 and L3 and wiring layers 43 and 44 on the first substrate 10.

The insulating layers L2 and L3 included in the second substrate 20 may be formed of the same material but may be formed of different materials.

Referring to FIG. 1, the second substrate 20 is disposed on only one side of the first substrate 10. However, the configuration is not limited thereto. Various modifications are possible, for example, the second substrate 20 may be disposed on both surfaces of the first substrate 10, and/or may be repeatedly stacked, as necessary.

The insulating protection layers 30a and 30b are disposed on the outermost side of the substrate part 40 to form the surface of the substrate part 40. The insulating protection layers 30a and 30b include openings to externally expose connection pads 41a and 44a.

The insulating protection layers 30a and 30b may be formed of an insulating resin material and may be formed using, for example, a solder resist. However, the materials and method of formation of insulating protection layers 30a and 30b are not limited thereto.

The insulating layers L1 to L3 of the substrate part 40 may be formed of a resin material having insulating properties. The insulating layers L1 to L3 may be formed of, for example, a thermosetting resin such as an epoxy resin, a thermoplastic resin such as polyimide, or a resin impregnated with a reinforcing material such as a glass fiber, or an inorganic filler, for example, a prepreg.

The insulating layer L1 of the first substrate 10 and the insulating layers L2 and L3 of the second substrate 20 may be formed of different materials. For example, the insulating layer L1 of the first substrate 10 may be formed of a polymer material, the insulating layers L2 and L3 of the second substrate 20 may be formed of an epoxy material, or vice versa. Alternatively, if necessary, the insulating layers L1 to L3 of the substrate part 40 may be formed of the same material. The above are merely examples, various modifications to the materials included in insulating layers L1, L2, and L3 are possible.

The wiring layers 41 to 44 are disposed on one surface or both surfaces of each of the insulating layers L1 to L3.

The wiring layers 41 to 44 may be formed by patterning a metal layer such as a copper foil (Cu foil) but are not limited thereto.

The connection pads 41a and 44a for mounting electronic components or connection terminals may be formed on the wiring layers 41 and 44 disposed on the outermost sides of the substrate part 40.

Various kinds of substrates (e.g., a ceramic substrate, a printed circuit board, a flexible substrate, a glass substrate, etc.) may be used as the substrate part 40.

The substrate part 40 is a multilayer substrate including wiring layers 41 to 44. According to FIG. 1, the substrate part 40 includes the four wiring layers 41 to 44, but the substrate part 40 is not limited thereto.

The substrate part 40 also includes an interlayer connection conductor 48 for electrically connecting the connection pads 41a and 44a formed on respective sides and the wiring layers 41 through 44 formed on the substrate part 40 with each other.

The interlayer connection conductor 48 is formed to penetrate each of the insulating layers L1 to L3.

A device accommodating part 49 in which the at least one first device 1 is embedded is formed in the substrate part 40.

The device accommodating part 49 is formed in the first substrate 10. However, the device accommodating part 49 may partially extend into the second substrate 20 as necessary.

An insulating member 49a is disposed in the device accommodating part 49. The insulating member 49a fills the device accommodating part 49 such that all the space of the device accommodating part 49 that accommodates the first device 1 is filled.

The insulating member 49a is formed of a material that has insulating properties and may be easily fill the device accommodating part 49. For example, the insulating member 49a is formed of the same material as the insulating layer L1 of the first substrate 10. For example, the insulating member 49a is formed by filling epoxy resin or polymer in a semi-cured state in the device accommodating part 49 and then performing curing on the epoxy resin or polymer. However, the insulating member 49a is not limited thereto.

The first device 1 embedded in the device accommodating part 49 is one of various electronic devices and includes, for example, a power amplifier or a front end module (FEM) incorporating the power amplifier.

As an example, the first device 1 includes the power amplifier, an RM filer, and an FEM element for wireless communications in which a switch device is embedded are used. However, the configuration described above is not limited thereto, and various devices may be applied as long as a device may be embedded in a substrate.

The first device 1 includes an active surface on which the terminal 1a is formed and an inactive surface opposite to the active surface. As described above, the second substrate 20 is used to rewire the terminal 1a of the first device 1. Accordingly, the second substrate 20 may be formed on one surface on which the active surface of the first device 1 is located.

Next, the device mounting portion S2 will be described.

The device mounting portion S2 includes the second device 2, a sealing portion 52, and a connection conductor 54.

The device mounting portion S2 is disposed on one surface of the device embedded portion S1.

The second device 2 is a surface mount type component and at least one is mounted on one surface of the device embedded portion S1. Therefore, the second device 2 is not limited in size and shape as long as the second device 2 may be mounted on the device embedded portion S1.

The second device 2 includes an active surface on which a terminal (not shown) is formed and an inactive surface opposite to the active surface.

The second device 2 is arranged such that the active surface having the terminal faces the active surface of the first device 1. Thus, the second device 2 is mounted on the second substrate 20 and is electrically connected to the first device 1 through the wiring layers 43 and 44 and the interlayer connection conductor 48 provided on the second substrate 20.

The second device 2 includes at least one signal processing device 2a (e.g., an RF IC) for wireless communications.

The signal processing device 2a is a device that performs RF signal processing and is electrically connected to the first device 1 described above.

The electrical path between the signal processing device 2 and the power amplifier (or the FEM device) is designed as short as possible if a wavelength of a wireless communications frequency is shortened by a unit of millimeter. To this end, in the semiconductor package 100, the signal processing device 2 is disposed in a position facing the first device 1.

Accordingly, the first device 1 and the signal processing device 2 are vertically connected to each other through the interlayer connection conductors 48 formed on the second substrate 20, and therefore, the electrical path between the first device 1 and the signal processing device 2 is minimized.

The second device 2 also includes various passive devices 2b, such as resistors, condensers, and inductors, for impedance matching and power supply bypassing.

At least one of the second devices 2 includes a heat dissipating member H.

Among the second devices 2, the signal processing device 2a generates a lot of heat during operations. Therefore, the heat dissipating member H is provided on the inactive surface of the signal processing device 2a.

The heat dissipating member H is provided to externally dissipate heat generated during operations of the signal processing device 2a, and is therefore formed of a metal material having high thermal conductivity.

As shown in FIG. 1, the heat dissipating member H is attached to the inactive surface of the signal processing device 2a through a bonding portion (not shown), and may be formed of, for example, a metal block made of copper. However, the heat dissipating member H is not limited thereto, and various modifications are possible, for example, by using a metal foil or by applying a metal material to the inactive surface of the signal processing device 2a to form the heat dissipating member H.

In FIG. 1, a case in which the heat dissipating member H is provided only in the signal processing device 2a is shown. However, the configuration is not limited thereto, and the heat dissipating member H may be easily added to other second devices 2 for any second device 2 that generates a large amount of heat.

The sealing portion 52 seals the second devices 2 mounted on the device embedded portion S1. Also, by filling the sealing portion 52 between the second devices 2 mounted on the device embedded portion S1, electrical short-circuiting between the second devices 2 may be prevented, and the second devices 2 may be protected from external impacts by surrounding outsides of the second devices 2 and fixing the second devices 2 into the semiconductor package 100.

One surface of the heat dissipating member H provided in the second device 2 is exposed externally of the sealing portion 52.

The sealing portion 52 described above is formed of an insulating material including a resin material such as an EMC (epoxy molding compound). However, the sealing portion 52 is not limited thereto.

The connection conductor 54 penetrates the sealing portion 52 and is disposed in the sealing portion 52. One end of the connection conductor 54 is bonded to the substrate part 40 and the other end is connected to a connection terminal 60.

The connection conductor 54 may be formed of a conductive material such as copper, gold, silver, aluminum, or alloys thereof.

The connection conductor 54 is formed in a conical shape having a smaller horizontal cross-sectional area toward the substrate part 40.

The connection terminal 60 may be bonded to the other end of the connection conductor 54. The connection terminal 60 electrically and physically connects the semiconductor package 100 and a main board (not shown) on which the semiconductor package 100 is mounted. The connection terminal 60 may be formed in form of a solder ball, but is not limited thereto.

As shown in FIG. 1, an antenna module is used as the second module M2. However, the second module M2 is not limited thereto, and various modules may be used as the second module M2 if necessary.

The second module M2 includes a dielectric substrate 72 having a high dielectric constant, a radiation part 74 disposed on one surface of the dielectric substrate 72, and electrode pads 76 arranged on the other surface of the dielectric substrate 72. Also, the second module M2 may further include an insulating protection layer 75 for protecting the radiation part 74 and the electrode pads 76.

As the dielectric substrate 72, an epoxy or polyimide-based polymer plastic substrate containing glass may be used, and a dielectric constant may be adjusted by controlling a glass content.

The electrode pads 76 are electrically connected to the radiation part 74 through the interlayer connection conductor 78.

The second module M2 is mounted on one surface of the first module M1 through a conductive adhesive 60a such as a solder.

Since the dielectric substrate 72 is formed of a material having a high dielectric constant, the second module M2 described with reference to FIG. 1 may reduce insertion loss and facilitate excellent impedance matching. Accordingly, a size of the antenna module may be minimized.

In the semiconductor package 100 according to the embodiment described above, the first module M1 and the second module M2 may be separately manufactured and then combined. Therefore, the semiconductor package 100 may select and use the dielectric substrate 72 which may increase antenna efficiency in manufacturing the second module M2.

Also, the FEM that is the first device 1 and the signal processing device 2a that is the second device 2 are vertically arranged, and at the same time, the active surfaces are arranged to face each other. Therefore, an electrical path between the first device and the signal processing device 2a may be minimized, and thus, signal loss may be minimized.

In addition, since the FEM, the signal processing device, and the antenna are integrated in a single semiconductor package, a mounting area may be reduced and an electrical path between the FEM, the signal processing device, and the antenna may be minimized as compared with a case in which the FEM, the signal processing device, and the antenna are separately manufactured and mounted on a main board.

Next, a manufacturing method of the above-described semiconductor package will be described.

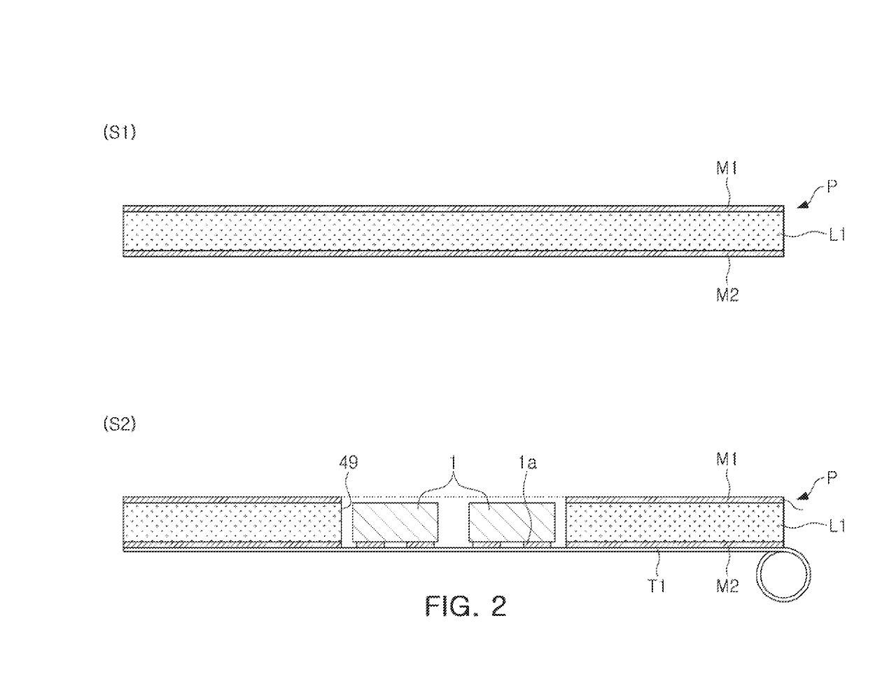

FIGS. 2 through 9 are diagrams illustrating an example of a method of manufacturing the semiconductor package shown in FIG. 1.

Referring to FIGS. 2 through 9, a stack plate P having metal layers M1 and M2 respectively formed on top and bottom surfaces of the insulating layer L1 is formed (S1) as shown in FIG. 2. For example, a copper clad laminate (CCL) is used as the stack plate P.

Subsequently, a portion of the stack plate P is removed to form the device accommodating part 49, and a tape T for supporting the first device 1 is attached to one surface of the stack plate P (S2).

The device accommodating part 49 is a through-hole and has a size corresponding to a size/shape of the first device 1 to be embedded therein.

The device accommodating part 49 may be easily formed by partially removing the stack plate P by using a laser. However, the device accommodating part 49 is not limited thereto, and various methods may be used so long as the device accommodating part 49 may be formed in the stack plate P, such as using a perforation method, a drilling method, or an etching method.

When the device accommodating part 49 is formed, the first device 1 on which the terminal 1a is formed on the active surface is disposed in the device accommodating part 49. At this time, the electronic device 1 is arranged so that the terminal 1a (or the active surface) comes into contact with the tape T.

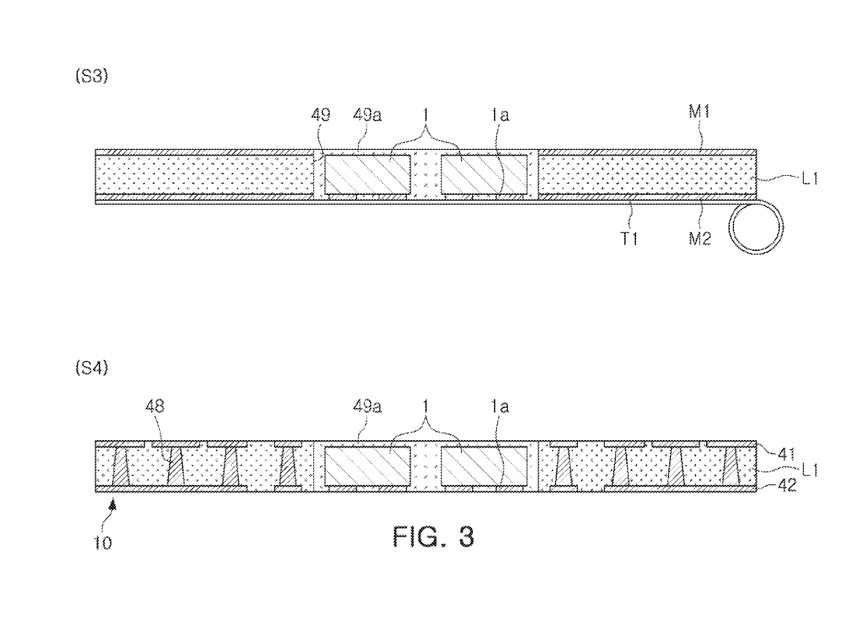

When the electronic device 1 is disposed in the device accommodating part 49, the insulating member 49a is filled in the device accommodating part 49 and then cured (S3) as shown in FIG. 3. The insulating member 49a flows into the device accommodating part 49 to fill a space formed in a periphery of the first device 1 and fix the first device 1.

The insulating member 49a may flow into the device accommodating part 49 in the form of liquid or gel to then be cured and formed.

Subsequently, after the tape T is removed, the metal layers M1 and M2 of the stack plate P are patterned to form the wiring layers 41 and 42 (S4).

In this step, the interlayer connection conductor 48 is formed in the stack plate P as well. The interlayer connection conductor 48 may be formed by forming a through hole in the insulating layer L1 and then applying or filling a conductive material in the through hole.

The wiring layers 41 and 42 may be formed through a photolithography method, but are not limited thereto.

Through the above process, the first substrate 10 is completed. The first substrate 10 is formed to be thicker than the first device 1 so that the first device 1 is be completely embedded.

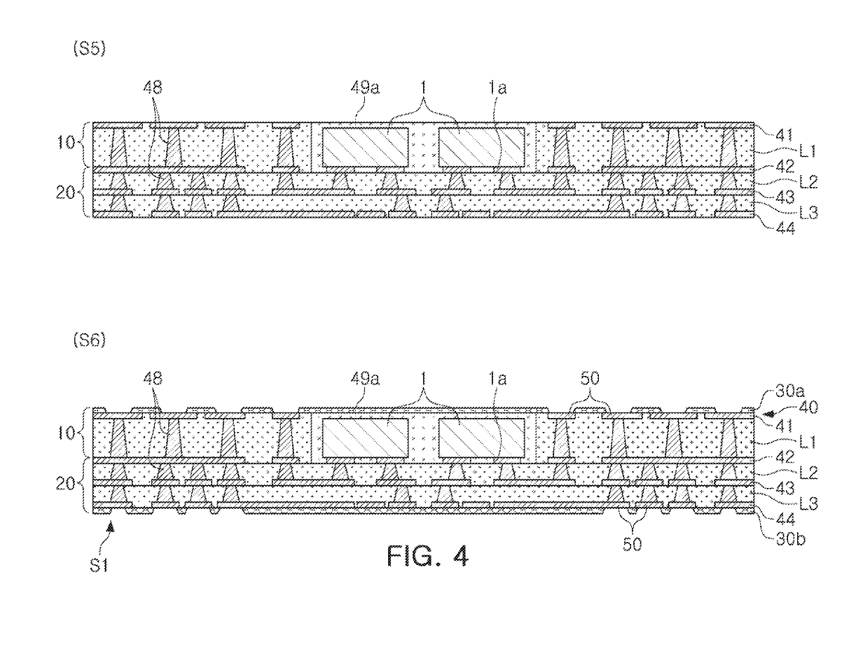

Next, as shown in FIG. 4, the second substrate 20 is formed on one surface (hereinafter referred to as a first surface) of both surfaces of the first substrate 10 (S5). The second substrate 20 is completed by repeatedly stacking the insulating layers L2 and L3 and then forming the interlayer connection conductors 48 in the insulating layers L2 and L3 and respectively forming the wiring layers 43 and 44 on the insulating layers L2 and L3. Such a process may be performed using a photolithography method, but is not limited thereto. The wiring layers 43 and 44 may also be formed by plating, vapor deposition, sputtering, etc.

Next, insulating protection layers 30a and 30b are formed on surfaces of the first substrate 10 and the second substrate 20, respectively (S6). At this time, openings are formed in the insulating protection layers 30a and 30b to expose the electrode pads 41a and 44a externally (see FIG. 1).

The insulating protection layers 30a and 30b may be formed as a solder resist. In addition, the insulating protection layers 30a and 30b may be formed in multiple layers as necessary.

Through the above-described process, the device embedded portion S1 is completed.

Subsequently, a device mounting portion S2 is formed on the device embedded portion S1.

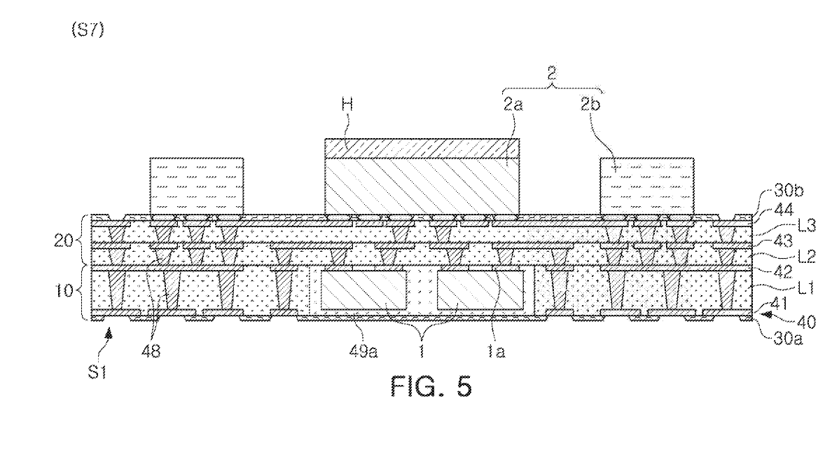

First, as shown in FIG. 5, the second devices 2 are mounted on one surface of the device embedded portion S1 (S7). The second devices 2 are mounted on a surface of the second substrate 20. The signal processing device 2a among the second devices 2 is mounted in a position as close as possible to the first device 1.

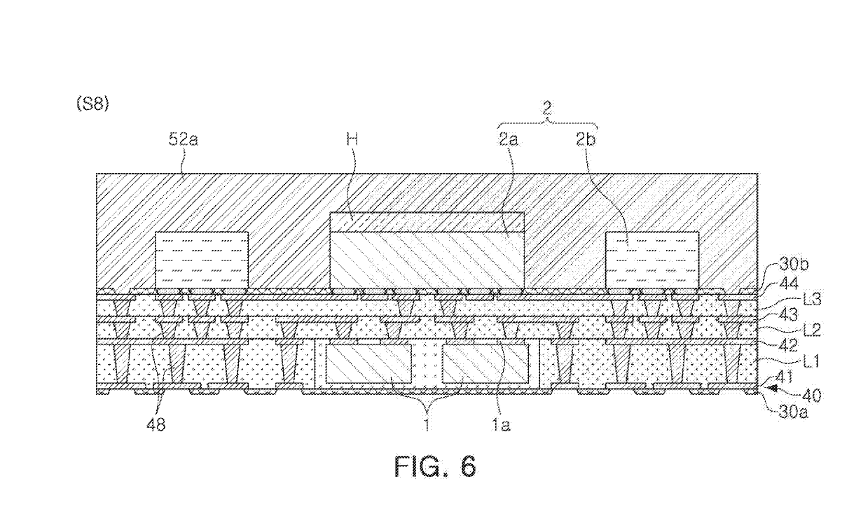

Next, a sealing member 52a for sealing the second devices 2 mounted on the device embedded portion S1 is formed (S8), as shown in FIG. 6. The sealing member 52a may be formed of an insulating material including a resin material such as EMC (epoxy molding compound). However, the sealing member 52a is not limited thereto.

The sealing member 52a may be formed by disposing the device embedded portion S1 in which the second devices 2 are mounted in a metal mold (not shown) and injecting molding resin into the metal mold.

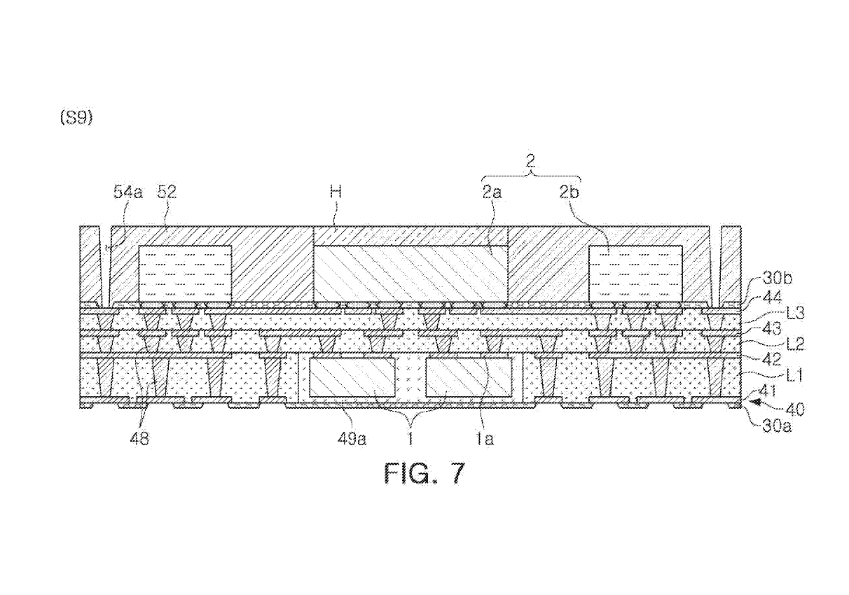

Thereafter, as shown in FIG. 7, the sealing member 52a (as described above and as previously shown in FIG. 6) is completed by partially removing the sealing member 52a to expose the signal processing device 2a externally, and forming a via hole 54a in the sealing member 52a (S9).

The sealing member 52a may be removed by polishing a portion covering the second device 2 through a grinder (not shown) or the like. The sealing member 52a is polished and removed until one surface of the heat dissipating member H disposed on the inactive surface of the signal processing device 2a is exposed externally, and the exposed surface of the heat dissipating member H and the sealing portion 52 are arranged on the same plane.

The via hole 54a may be formed through a laser drilling method.

During this process, the overall shape of the via hole 54a is formed to be a conical shape in which a horizontal cross-sectional area is reduced as the via hole 54a becomes closer to the device embedded portion S1.

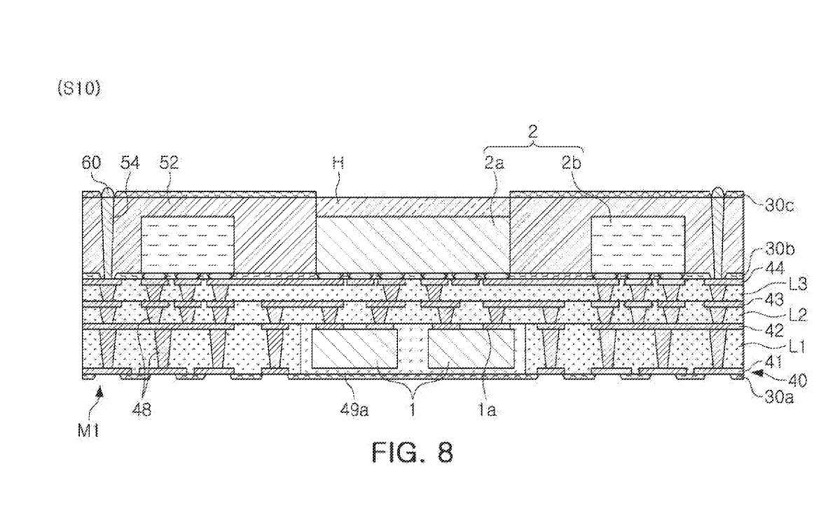

Subsequently, the connection conductor 54 is formed in the via hole 54a (S10) as shown in FIG. 8. The connection conductor 54 may be formed through a plating method. When the connection conductor 54 is made of copper (Cu), copper plating may be performed. The plating method may include, but is not limited thereto, both or either of electroless plating and electrolytic plating.

For example, the connection conductor 54 may be formed only by electrolytic plating. In this case, the connection conductor 54 may be formed by sequentially filling the via holes 54a from an external electrode terminal 16 of the substrate 10 using an electrolytic plating wiring (not shown) formed in the device embedded portion S1.

The sealing portion 52 may be formed of EMC. In general, plating, i.e. bonding of metal, on a surface of EMC, which is a thermosetting resin, is very difficult.

Thus, mechanical interlocking, hooking, anchoring theory, or anchoring effect may be used to plate a conductor on the EMC surface. These terms refer to a mechanism in which an adhesive penetrates into irregular structures (i.e. irregularities) on a surface of an adherend and is bonded by mechanical engagement.

For example, a method of forming an inner surface of the via hole 54a formed by EMC as rough as possible and combining the plating material with the inner surface of the via hole 54a in the anchor effect in the plating method may be used. However, the method is not limited thereto.

When the connection conductor 54 is formed in the via hole 54a, the insulating protection layer 30c is formed on the surface of the sealing portion 52. At this time, the connection conductor 54 and the heat dissipating member H are exposed externally through an opening formed in the insulating protection layer 30c.

Then, the connection terminal 60 is bonded to the connection conductor 54 to complete the first module M1. However, the connection terminal 60 may be omitted, or may be bonded to the connection conductor 54 after the second module M2 is mounted on the first module M1.

Then, the second module M2 is stacked on the first module M1.

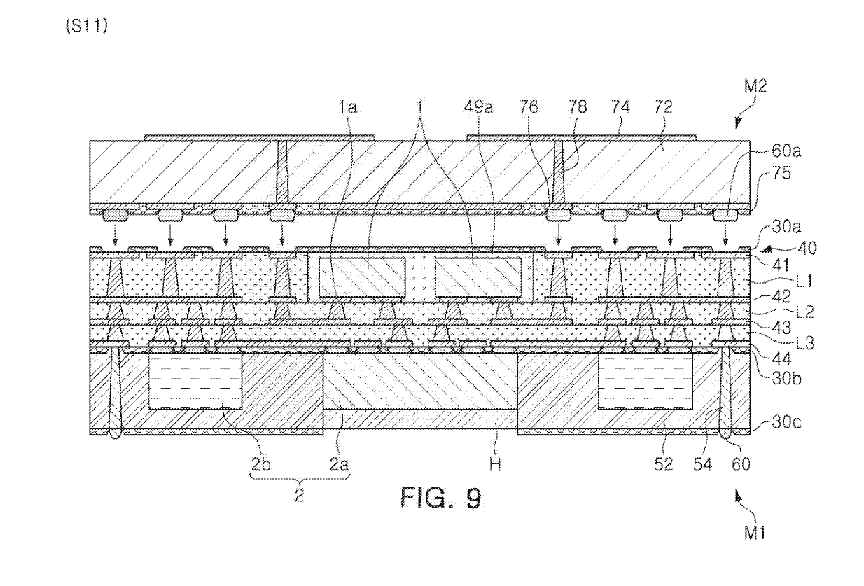

A method of manufacturing the second module M2 will be briefly described with reference to FIG. 9.

A radiation part 74 is formed on one surface of the dielectric substrate 72 having a high dielectric constant and the connection pads 76 are formed on the other surface. Thereafter, the interlayer connection conductor 78 is formed in the dielectric substrate 72 to electrically connect the radiation part 74 and the connection pads 76. The above process may be performed by a photolithography method, but is not limited thereto.

Thereafter, the insulating protection layer 75 is formed on the other surface of the dielectric substrate 72 on which the connection pad 76 is formed to complete the second module M2.

The completed second module M2 is stacked on the first module M1 (S11) as shown in FIG. 9.

The second module M2 may be bonded to the first module M1 via the conductive adhesive 60a such as a solder ball.

The semiconductor package described above is not limited to the above-described embodiment, and various modifications are possible.

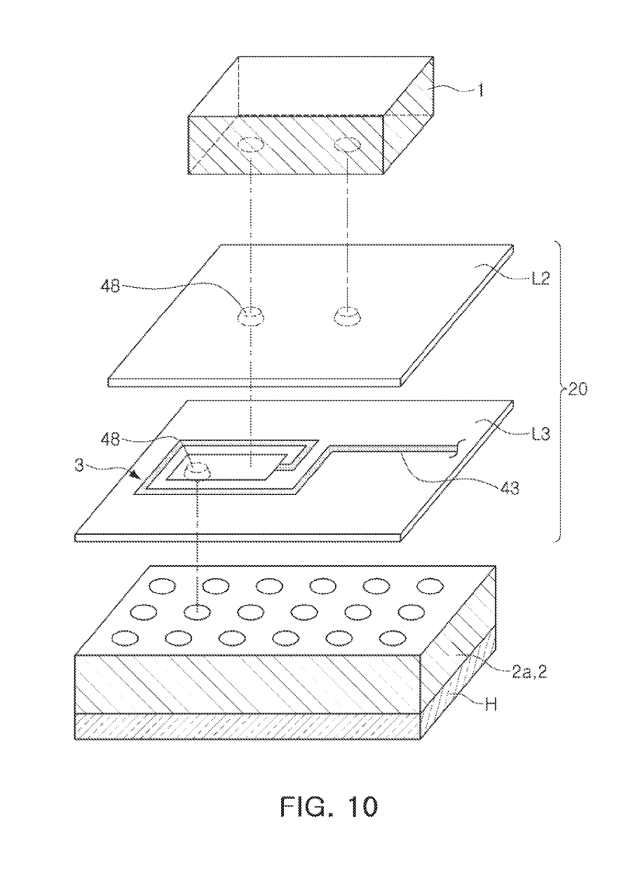

FIG. 10 is an exploded perspective view of an enlarged portion of the semiconductor package shown in FIG. 1 in which the first device 1 and the second device 2 are connected.

Referring to FIG. 10, the semiconductor package includes a third device 3 for impedance matching on an electrical path connecting the first device 1 and the second device 2.

The third device 3 is located in the second substrate 20 and is used for impedance matching between an FEM device (e.g. first device 1) and the signal processing device 2a (e.g. second device 2).

The third device 3 may also be manufactured through the wiring layer 43 formed in the second substrate 20 during a process of manufacturing the second substrate 20.

Referring to FIG. 10, in the present embodiment, the third device 3 is composed of an inductor. However, the third device 3 is not limited thereto, and may be implemented in various forms as long as the third device 3 may be realized through the wiring layer 43 such as a capacitor or a resistor and may be used for impedance matching.

When impedance matching is performed between the first device 1 (for example, an FEM device) and the second device 2 (for example, a signal processing device), at least one passive device needs to be disposed on an electrical path connecting the first device 1 and the second device 2.

Therefore, when the first device 1 and the second device 2 are horizontally mounted on one substrate, since a passive device is disposed between the first device 1 and the second device 2, the electrical path connecting the first device 1 and the second device 2 may be elongated, causing signal loss when using a millimeter band frequency. Also, when a passive device is mounted on a substrate by a surface mounting method, a parasitic component may be caused due to a connection pad for mounting the passive device, which may cause deterioration of performance of the semiconductor package.

However, since the first device 1 and the second device 2 are vertically arranged, the semiconductor package described above may minimize the electrical path between the first device 1 and the second device 2. Since the third device 3 is formed in the second substrate 20 disposed between the first substrate 20 and the second substrate 30, the electrical path does not increase even if the third device 3 is added. Therefore, the loss of the signal may be minimized, and the above-mentioned parasitic component may be prevented from being caused.

As set forth above, in the semiconductor package, an FEM (first device) and a signal processing device (second device) are vertically arranged, and at the same time, active surfaces are arranged to face each other. Therefore, an electrical path between the first and second devices may be minimized, and thus a signal loss may be minimized.

Further, even if a third device is disposed between the first device and the second device, the electrical path between the first device and the second device is not increased. Therefore, loss of a signal may be minimized, and an unnecessary parasitic component may be prevented from being caused.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor package, comprising:
a device embedded portion comprising a first substrate having a first device embedded therein and a second substrate disposed on the first substrate;
a device mounting portion comprising a second device disposed on the device embedded portion and a sealing portion for sealing the second device; and
a second module mounted on a surface of the device embedded portion that is opposite of a surface on which the device mounting portion is disposed.

2. The semiconductor package of claim 1, wherein the first device and the second device are arranged such that respective active surfaces face each other with the second substrate therebetween.

3. The semiconductor package of claim 1, wherein the first device and the second device are electrically connected through the second substrate.

4. The semiconductor package of claim 2, wherein the first device is a front end module (FEM) device for wireless communications and the second device is a signal processing device for wireless communications.

5. The semiconductor package of claim 2, further comprising a heat dissipating member comprising a metal material disposed on an inactive surface of the second device, one surface of the heat dissipating member being exposed externally of the sealing portion.

6. The semiconductor package of claim 1, wherein the second module comprises:
a dielectric substrate;
a radiation part disposed on a first surface of the dielectric substrate;
connection electrodes disposed in a second surface of the dielectric substrate opposite the first surface and bonded to the device embedded portion by a conductive bonding member; and
an interlayer connection conductor disposed on the dielectric substrate and electrically connecting the radiation part and the connection electrodes.

7. The semiconductor package of claim 1, wherein the device mounting portion is disposed in the sealing portion and comprises connection conductors having one end electrically connected to the device embedded portion and the other end exposed externally of the sealing portion.

8. The semiconductor package of claim 1, wherein the second substrate comprises a third device comprising alternately stacked one or more insulating layers and one or more wiring layers disposed on the first substrate.

9. The semiconductor package of claim 8, wherein the third device is connected to a path electrically connecting the first device and the second device and is used for impedance matching of the first device and the second device.

10. The semiconductor package of claim 8, wherein the third device comprises an inductor or a capacitor.

11. A method of manufacturing a semiconductor package, the method comprising:
forming a device embedded portion in which a first device is embedded in a substrate;
mounting a second device on one a first of the device embedded portion; and
mounting an antenna module on a second surface of the device embedded portion opposite the first surface.

12. The method of claim 11, wherein the mounting of the second device comprises mounting the second device such that an active surface of the first device and an active surface of the second device face each other.

13. The method of claim 11, wherein the forming of the device embedded portion comprises:
embedding the first device in a first substrate; and
forming a second substrate on the first substrate by alternately stacking one or more insulating layers and one or more wiring layers.

14. The method of claim 13, wherein the forming of the second substrate further comprises: forming a third device electrically connected to the wiring layer,
wherein the third device is electrically connected to a path electrically connecting the first device and the second device.

15. The method of claim 11, further comprising:
forming a sealing portion configured to seal the second device; and
forming connection conductors penetrating the sealing portion and comprising a first end electrically connected to the device embedded portion and a second end exposed externally of the sealing portion.

16. The method of claim 15, wherein the forming of the sealing portion comprises partially removing the sealing portion to partially expose the second device.
